(19) United States
(12) Patent Application Publication
(10) Pub. No.: US 2008/0070328 A1
(43) Pub. Date: Mar. 20, 2008

(54) Method of fabricating semiconductor device

(75) Inventor: Mitsuhiro Omura, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/889,292

(22) Filed: Aug. 10, 2007

(30) Foreign Application Priority Data
Sep. 15, 2006 (JP) 2006-251023

(51) Int. Cl. H01L 21/00

(52) U.S. Cl. 438/9; 257/E21.218

(57) ABSTRACT

A method of fabricating a semiconductor device according to an embodiment of the present invention includes: forming a film to be processed having a first film thickness on a semiconductor substrate; forming a region, within the film to be processed, having a second film thickness thinner than the first film thickness by processing a part of the film to be processed; processing the film to be processed having the region of the second film thickness formed therein by utilizing a dry etching method while a change in characteristic value of a plasma is monitored; detecting a first timing at which a member right under the region, within the film to be processed, which had the second film thickness before the processing performed by utilizing the dry etching method begins to be exposed in accordance with the change in characteristic value of the plasma during the processing performed by utilizing the dry etching method; and estimating a second timing right before a member right under a region, of the film to be processed, which had the first film thickness before the processing performed by utilizing the dry etching method begins to be exposed in accordance with the first timing, and changing an etching condition for the dry etching over to another one at the second timing.

### CROSS-REFERENCE TO RELATED APPLICATIONS

This application is based upon and claims the benefit of priority from prior Japanese Patent Application No. 2006-251023, filed on Sep. 15, 2006, the entire contents of which are incorporated herein by reference.

### BACKGROUND OF THE INVENTION

The present invention relates to a method of fabricating a semiconductor device for which highly precise processing is performed by utilizing a dry etching technique.

A technique for forming an offset spacer or the like by utilizing a film deposition technique, and a dry etching technique is used in a conventional method of fabricating a semiconductor device. This technique, for example, is described in Japanese Patent KOKAI No. 2006-186012.

With this sort of technique, in a process for forming an offset spacer, after a gate electrode is formed on a silicon substrate through a gate insulating film, a silicon oxide film or a silicon nitride film having a thickness of about 10 nm are deposited on the gate electrode, and the silicon oxide film or the silicon nitride film is anisotropically etched so as to be left only on a sidewall of the gate electrode by utilizing a dry etching technique. In this case, it is preferable that an amount of abraded base silicon substrate is suppressed to about 2 nm or less, and a portion of the offset spacer in the vicinity of a boundary between the silicon substrate and the offset spacer has a vertical shape. When the portion of the offset spacer in the vicinity of the boundary between the silicon substrate and the offset spacer has no vertical shape, but has a skirt shape, the skirt shape of this portion may exert a bad influence on the later ion implantation process.

Hereinafter, concrete processes will be described. When the silicon oxide film or the silicon nitride film is etched, the dry etching method using a fluorocarbon system gas as an etching gas is utilized. Here, giving the silicon oxide film as an example, in order to process the silicon oxide film so that the position of the offset spacer in the vicinity of the boundary between the silicon substrate and the offset spacer has the vertical structure, it is necessary to reduce a carbon/fluorine ratio (hereinafter referred to as a C/F ratio) of the fluorocarbon system gas. Also, in order to reduce the amount of abraded base silicon substrate by increasing an etching selectivity between the offset spacer and the base silicon substrate, it is necessary to increase the C/F ratio.

For this reason, in general, a step etching method is used. More specifically, this step etching method is such that the silicon oxide film or the silicon nitride film is processed under an etching condition that the C/F ratio is small, and the etching selectivity between the silicon oxide film or the silicon nitride film, and the base silicon substrate is small until the surface of the base silicon substrate is exposed, while during an over-etching process after the surface of the base silicon substrate is exposed, the silicon oxide film or the silicon nitride film is processed under another etching condition that the C/F ratio is large, and the etching selectivity between the silicon oxide film or the silicon nitride film, and the base silicon substrate is large.

However, this step etching method involves a problem that it is difficult to control a step changing timing. Normally, in order to change the etching step over to another suitable one with an excellent controllability, an end point monitor is used which monitors an emission intensity of a plasma used in the dry etching process, and judges a step changing point in accordance with a change in emission intensity of the plasma. When the silicon oxide film is etched by using the fluorocarbon system gas as the etching gas, it is observed that a light with a wavelength of 440 nm is emitted due to an Si—F bond during the etching. However, the emission intensity of the plasma which emits the light with the wavelength of 440 nm decreases because an amount of SiFₓ as an etching product decreases when the surface of the base silicon substrate begins to be seen. An end point of the etching is detected by detecting a decrease in emission intensity of the plasma.

However, detecting the decrease in emission intensity of the plasma by using the end point monitor means that the surface of the base silicon substrate has already began to be exposed in a part within a wafer surface. Thus, the base silicon substrate is etched under the etching condition that the C/F ratio is small, and the etching selectivity between the silicon oxide film or the silicon nitride film, and the base silicon substrate is small. In other words, the etching condition cannot be changed over to another one right before the surface of the base silicon substrate is exposed, and thus the etching cannot help but abrades the base silicon substrate. For this reason, it becomes very difficult to suppress the amount of abraded base silicon substrate to several nano meters or less.

### BRIEF SUMMARY OF THE INVENTION

A method of fabricating a semiconductor device according to one embodiment of the present invention includes:

forming a film to be processed having a first film thickness on a semiconductor substrate;

forming a region, within the film to be processed, having a second film thickness thinner than the first film thickness by processing a part of the film to be processed;

processing the film to be processed having the region of the second film thickness formed therein by utilizing a dry etching method while a change in characteristic value of a plasma is monitored;

detecting a first timing at which a member right under the region, within the film to be processed, which had the second film thickness before the processing performed by utilizing the dry etching method begins to be exposed in accordance with the change in characteristic value of the plasma during the processing performed by utilizing the dry etching method; and

estimating a second timing right before a member right under a region, of the film to be processed, which had the first film thickness before the processing performed by utilizing the dry etching method begins to be exposed in accordance with the first timing, and changing an etching condition for the dry etching over to another one at the second timing.

A method of fabricating a semiconductor device according to another embodiment of the present invention includes:

forming a gate electrode on a semiconductor substrate through a gate insulating film;

forming a film to be processed having a first film thickness on the semiconductor substrate, and an upper surface and a side surface of the gate electrode;

applying an organic film onto the film to be processed;

etching back the organic film by utilizing a dry etching method until a portion of the film to be processed overlying the upper surface of the gate electrode is exposed;

thinning the exposed portion of the film to be processed overlying the upper surface of the gate electrode by utilizing a dry etching method until the exposed portion of the film to be processed has a second film thickness;

removing the organic film by utilizing an ashing technique after thinning the exposed portion of the film to be processed overlying the upper surface of the gate electrode by utilizing the dry etching method;

processing the film to be processed by utilizing a dry etching method while a change in characteristic value of a plasma is monitored after removing the organic film by utilizing the ashing technique;

detecting a first timing at which the gate electrode begins to be exposed in accordance with the change in characteristic value of the plasma;

estimating a second timing right before the semiconductor substrate begins to be exposed in accordance with the first timing, and changing an etching condition for the dry etching over to another one at the second timing; and

removing the film to be processed overlying the semiconductor substrate, thereby leaving the film to be processed on the side surface of the gate electrode.

### BRIEF DESCRIPTION OF THE DRAWING

FIGS. 1A to 1K are respectively cross sectional views showing processes for fabricating a semiconductor device according to a first embodiment of the present invention;

FIG. 2 is a flow chart showing processes for fabricating an offset spacer in the semiconductor device fabricated by utilizing the fabricating method according to the first embodiment of the present invention;

FIG. 3 is a graphical representation showing a relationship between an etching time of a spacer material film shown in FIGS. 1A to 1K, and an emission intensity of a plasma which emits a light with a wavelength of 440 nm;

FIGS. 4A and 4B are respectively cross sectional views showing processes for fabricating a semiconductor device according to a second embodiment of the present invention; and

FIGS. 5A to 5C are respectively cross sectional views showing processes for fabricating a semiconductor device according to a third embodiment of the present invention.

### DETAILED DESCRIPTION OF THE INVENTION

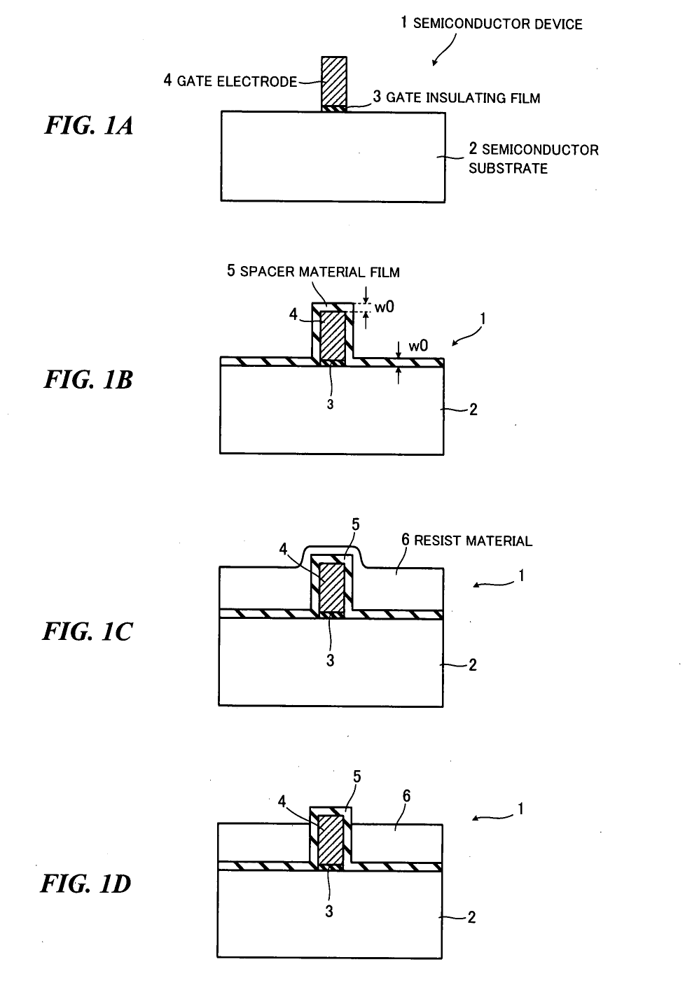

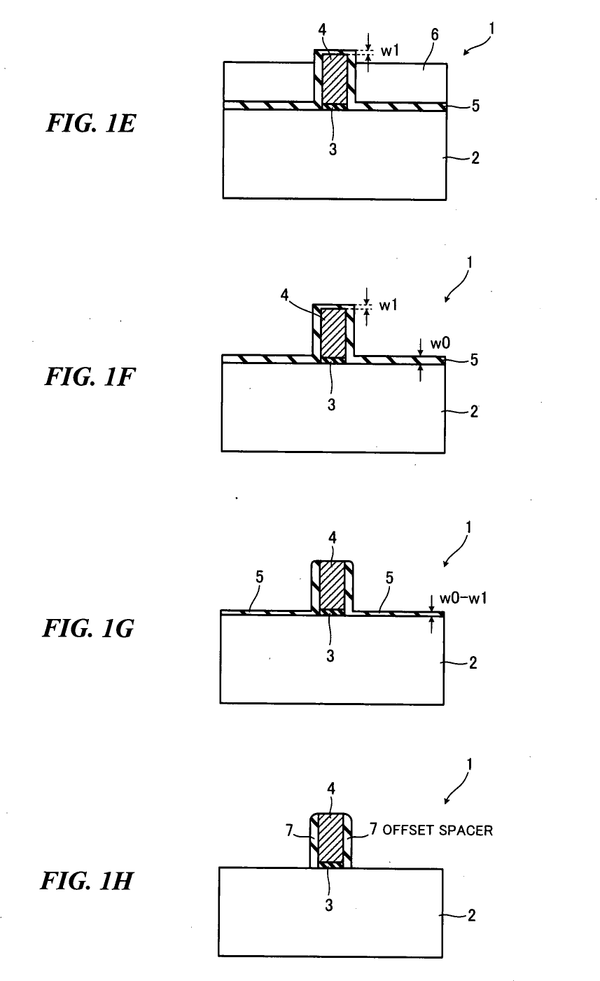

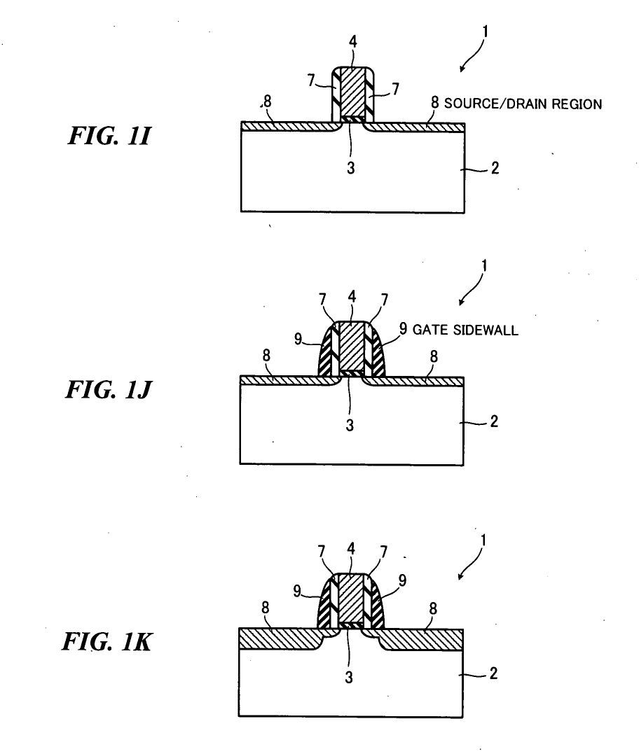

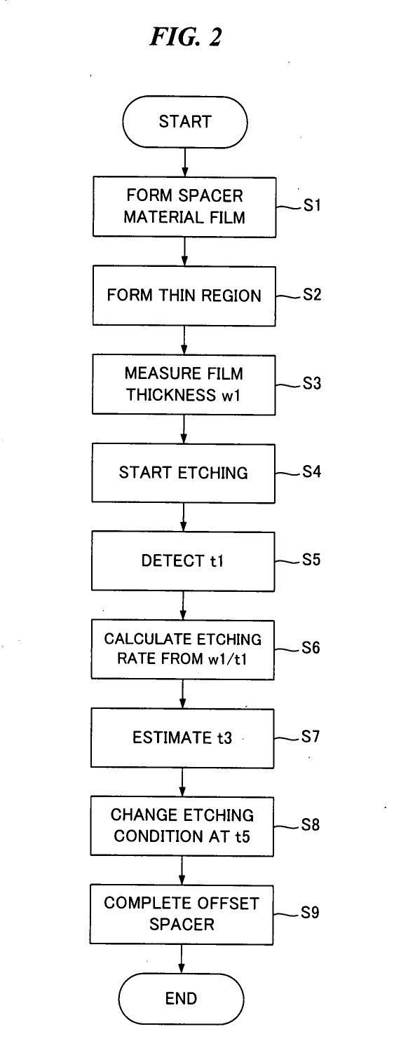

FIGS. 1A to 1K are respectively cross sectional views showing processes for fabricating a semiconductor device according to a first embodiment of the present invention. In addition, FIG. 2 is a flow chart showing processes for fabricating an offset spacer in the semiconductor device fabricated by utilizing the fabricating method according to the first embodiment of the present invention.

Firstly, as shown in FIG. 1A, a gate electrode 4 made of polycrystalline Si, polycrystalline SiGe or the like is formed on a semiconductor substrate 2 made of a single crystal Si or the like through a gate insulating film 3 made of SiON or the like by utilizing a film deposition technique, a lithography technique, a dry etching technique, a wet etching technique and the like.

Next, as shown in FIG. 1B, a spacer material film 5 made of a silicon oxide or the like is deposited so as to cover the semiconductor substrate 2 and the gate electrode 4 and so as to have a film thickness w0 (Step S1 in FIG. 2).

Next, as shown in FIG. 1C, a resist material 6 is applied onto the spacer material film 5, and as shown in FIG. 1D, the resist material 6 is etched back by utilizing a dry etching method using an etching gas such as an O₂ gas, thereby exposing a first portion of the spacer material film 5 overlying a surface of an upper portion of the gate electrode 4. Note that, at this time, a coated type organic film typified by the resist material 6 can cover the entire surface of the semiconductor substrate 2 with its viscosity being adjusted so that a portion of the coated type organic film located above the upper portion of the gate electrode 4 becomes thin, and a portion of the coated type organic film, other than the portion thereof located above the upper portion of the gate electrode 4, located above the surface of the semiconductor substrate 2 becomes thick. As a result, the first portion of the spacer material film 5 overlying the surface of the upper portion of the gate electrode 4 can be readily and selectively exposed in a subsequent etch back process.

Moreover, in the case of the etching, using O₂ as the etching gas, for the resist material 6, the etching gas does not contain therein F which is used to etch the silicon oxide or the silicon nitride. As a result, the spacer material film 5 is not etched at all during each of the etch back and ashing for the resist material 6, and thus the etching selectivity between the resist material 6 and the spacer material film 5 made of the silicon oxide or the silicon nitride can be made approximately infinite.

Next, as shown in FIG. 1E, the exposed first portion of the spacer material film 5 overlying the surface of the upper portion of the gate electrode 4 is etched by, for example, about 1 nm by utilizing a dry etching method using an F containing gas such as a fluorocarbon system gas (Step S2 in FIG. 2).

Next, as shown in FIG. 1F, the resist material 6 is removed away by utilizing an ashing technique or the like, and a film thickness w1 of the first portion of the spacer material film 5 overlying the surface of the upper portion of the gate electrode 4 is measured by using an instrument for measuring a film thickness (Step S3 in FIG. 2). Note that, the film thickness, w0, of a second portion of the spacer material film 5 overlying the surface of the semiconductor substrate 2 is equal to or approximately equal to a film thickness value of the spacer material film 5 right after the film deposition in Step S1 in FIG. 2.

After that, the spacer material film 5 is started to be etched under an etching condition that a C/F ratio (a carbon/fluorine ratio) is small, and the etching selectivity between the spacer material film 5 and the semiconductor substrate 2 is small by using an etching gas such as the fluorocarbon system gas while the emission intensity of the plasma is monitored by using an end point monitor (Step S4 in FIG. 2).

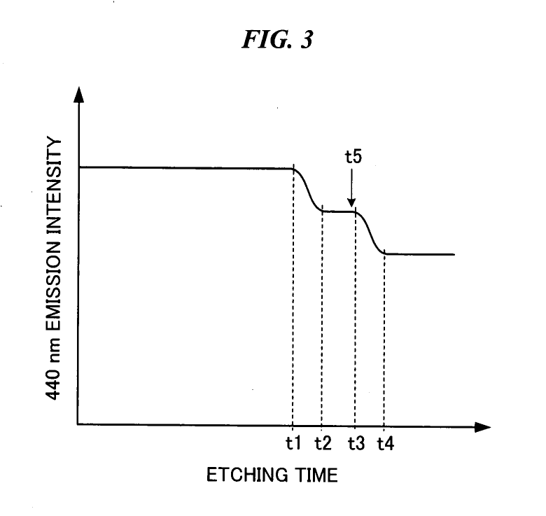

FIG. 3 is a graphical representation showing a relationship between an etching time of the spacer material film, and the emission intensity of the plasma which emits a light with a wavelength of 440 nm. The emission of the light with the wavelength of 440 nm is generated due to an Si—F bond. For this reason, the strong light emission is observed while the spacer material film 5 is etched. However, when the surface of the upper portion of the gate electrode 4 underlying as the base the first portion of the spacer material film 5, or the surface of the semiconductor substrate 2 underlying as the base the second portion of the spacer material film 5 begins to be exposed, the emission intensity comes to be weakened because an amount of SiFₓ as an etching product decreases.

Here, the spacer material film 5 has the first portion with the film thickness w1 overlying the surface of the upper portion of the gate electrode 4, and the second portion with the film thickness w0 overlying the surface of the semiconductor substrate 2. Therefore, the spacer material film 5 has two time points at each of which the emission intensity of the plasma which emits the light with the wavelength of 440 nm decreases. That is to say, one time point is a time at which the first portion with the film thickness w1 of the spacer material film 5 overlying the surface of the upper portion of the gate electrode 4 is etched, so that the surface of the upper portion of the gate electrode 4 underlying the first portion of the spacer material film 5 begins to be exposed. Also, the other time point is a time at which the second portion with the film thickness w0 of the spacer material film 5 overlying the surface of the semiconductor substrate 2 is etched, so that the surface of the semiconductor substrate 2 underlying the second portion of the spacer material film 5 begins to be exposed. In FIG. 3, t1 represents a time at which the surface of the upper portion of the gate electrode 4 underlying the first portion of the spacer material film 5 begins to be exposed, t2 represents a time at which the first portion of the spacer material film 5 overlying the surface of the upper portion of the gate electrode 4 is perfectly removed away, t3 represents a time at which the surface of the semiconductor substrate 2 underlying the second portion of the spacer material film 5 begins to be exposed, and t4 represents a time at which the second portion of the spacer material film 5 overlying the surface of the semiconductor substrate 2 is perfectly removed away. In addition, t5 represents a time right before the time t3, that is, a time right before the surface of the semiconductor substrate 2 underlying the second portion of the spacer material film 5 begins to be exposed.

When the time t1 at which the surface of the upper portion of the gate electrode 4 underlying the first portion of the spacer material film 5 begins to be exposed after the etching is started is detected by using the end point monitor (Step S5 in FIG. 2), an etching rate can be calculated in real time in accordance with a calculation of w1/t1 because the film thickness w1 is previously measured by using the instrument for measuring a film thickness (Step S6 in FIG. 2). FIG. 1G shows a state of the semiconductor device 1 in the middle of fabrication at the time t1. A film thickness of the second portion of the spacer material film 5 overlying the surface of the semiconductor substrate 2 at this time is equal to or approximately equal to a value of (w0-w1).

In addition, the time t3 at which the second portion with the film thickness w0 of the spacer material film 5 overlying the surface of the semiconductor substrate 2 is etched, so that the surface of the semiconductor substrate 2 underlying the second portion of the spacer material film 5 begins to be exposed can be estimated in accordance with the etching rate thus calculated (Step S7 in FIG. 2). Performing the calculation described above in real time is sufficiently possible by executing calculation processing at the same level as that of the calculation for the end point using the end point monitor.

Next, as shown in FIG. 1H, at the time t5 right before the time t3, the etching condition is changed over to another suitable one that the C/F ratio is made larger than that of the former etching condition, and the etching selectivity between the spacer material film 5 and the semiconductor substrate 2 is made larger than that of the former etching condition, and the etching is performed under this etching condition (Step S8 in FIG. 2) to remove the second portion of the spacer material film 5 overlying the surface of the semiconductor substrate 2, thereby forming an offset spacer 7 from a part of the spacer material film 5 left on the side surfaces of the gate insulating film 3 and the gate electrode 4 (Step S9 in FIG. 2).

Note that, w1 preferably ranges from about 70% to about 90% of w0. The reason for this is as follows. That is to say, when w1 is smaller than 70% of w0, the dispersion of an amount of etched spacer material film 5 after a lapse of the time t1 becomes large because the film thickness (w0-w1) becomes too thick, and also the precision for the calculated etching rate is poor. As a result, it becomes difficult to change the etching condition to another suitable one right before the surface of the semiconductor substrate 2 underlying the second portion of the spacer material film 5 begins to be exposed. On the other hand, when w1 exceeds 90% of w0, the surface of the semiconductor substrate 2 underlying the second portion of the spacer material film 5 may begin to be exposed before the first portion of the spacer material film 5 overlying the surface of the upper portion of the gate electrode 4 is perfectly removed away because a difference between the film thicknesses w0 and w1 becomes too small.

Next, as shown in FIG. 1I, ions of a p-type impurity such as B, BF₂ or In in the case of a p-channel MOSFET, and ions of an n-type impurity such as As or P in the case of an n-channel MOSFET are implanted into the unmasked region of the semiconductor substrate 2 by utilizing an ion implantation method, thereby forming an extension region of a source/drain region 8. After that, a suitable heat treatment is performed, thereby activating the impurity ions thus implanted thereinto.

Next, as shown in FIG. 1J, a gate sidewall 9 made of a silicon nitride film or the like is formed on the side surfaces of gate insulating film 3 and the gate electrode 4 through the offset spacer 7.

Next, as shown in FIG. 1K, ions of a p-type impurity such as B, BF₂ or In in the case of the p-channel MOSFET, and ions of an n-type impurity such as As or P in the case of the n-channel MOSFET are implanted into the unmasked region of the semiconductor substrate 2 by utilizing the ion implantation method, thereby forming the source/drain region 8. After that, a suitable heat treatment is performed, thereby activating the impurity ions thus implanted thereinto.

Thereafter, while not illustrated in these figures, an interlayer insulating film, contacts, wirings and the like are formed.

According to the first embodiment of the present invention, the part of the spacer material film 5 is previously thinned, and in this state, the dry etching is performed while the emission intensity of the plasma is monitored, which results in that the etching rate can be calculated in real time, and the etching condition can be changed to another suitable one at the suitable time point. As a result, the offset spacer 7 having the approximately vertical portion in the vicinity of the boundary between the semiconductor substrate 2 and the offset spacer 7 can be formed without largely abrading the surface of the semiconductor substrate 2.

Note that, the etching condition or the like is suitably controlled such that the etching gas is changed over to another suitable one in each of the processes, that is, O₂ is used for each of the etch back and ashing for the resist material, the etching gas such as the fluorocarbon system gas is used for the etching for the silicon oxide, and so forth, which results in that the processes after the resist material is applied onto the spacer material film 5 (refer to FIG. 1C) can be carried out continuously within the same dry etching chamber. As a result, the throughput can be greatly improved because of simplification of the fabricating processes.

In addition, when, for example, a plurality of semiconductor devices 1 are fabricated, if one semiconductor device 1 is fabricated in accordance with the fabricating method of this embodiment, it is possible to know the film thickness w1 of the first portion of the spacer material film 5 overlying the surface of the upper portion of the gate electrode 4. Therefore, the process for measuring the film thickness w1 can be omitted from the later processes for fabricating the other semiconductor devices 1. The process for measuring the film thickness w1 must be carried out for the semiconductor device 1 which is brought out from the chamber once. Thus, the omission of the process for measuring the film thickness w1 makes it possible to shorten the time and to save the labor.

In addition, the film thickness w0 may be measured by using the instrument for measuring a film thickness similarly to the measurement of the film thickness w1. As a result, it is possible to further enhance the etching precision.

A second embodiment of the present invention relates to a method of fabricating a semiconductor device 1 in which the process for measuring the film thickness w1 of the first portion of the spacer material film 5 overlying the surface of the upper portion of the gate electrode 4 is omitted. Note that, descriptions of the same respects as those of the first embodiment are omitted here for the sake of simplicity.

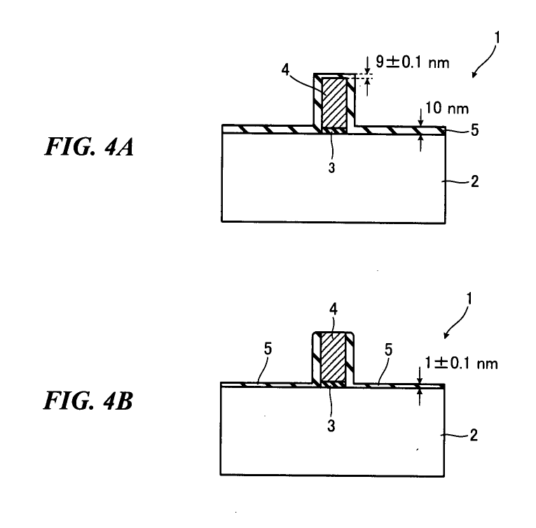

FIGS. 4A and 4B are respectively cross sectional views showing processes for fabricating a semiconductor device according to the second embodiment of the present invention.

Firstly, up to the process (Step S2 in FIG. 2) for etching the exposed first portion of the spacer material film 5 overlying the surface of the upper portion of the gate electrode 4 by, for example, 1 nm by utilizing the dry etching method using the etching gas such as the fluorocarbon system gas as shown in FIG. 1E is carried out similarly to the first embodiment. After that, the resist material 6 is removed away by utilizing the ashing technique or the like. In this case, the measurement of the film thickness of the first portion of the spacer material film 5 (Step S3 in FIG. 2) shown in FIG. 1F is not carried out.

At this time, an error of about ±10% must be taken into consideration because the amount of etched spacer material film 5 disperses due to an influence of a change of the etching rate with time. For this reason, as shown in FIG. 4A, when the first portion of the spacer material film 5, which has a thickness of about 10 nm, overlying the surface of the upper portion of the gate electrode 4 is etched by 1 nm, the first portion has a thickness of 9±0.1 nm.

Next, the spacer material film 5 is started to be etched under an etching condition that the C/F ratio is small, and the etching selectivity between the spacer material film 5 and the semiconductor substrate 2 is small by using the etching gas such as the fluorocarbon system gas while the emission intensity of the plasma is monitored by using the end point monitor (Step S4 in FIG. 2).

After start of the etching for the spacer material film 5, the time t1 shown in FIG. 3 is detected by using the end point monitor (Step S5 in FIG. 2). In this case, t1 shown in FIG. 3 is the time at which the first portion, of the spacer material film 5, having the film thickness of 9±0.1 nm and overlying the surface of the upper portion of the gate electrode 4 is etched, so that the surface of the upper portion of the gate electrode 4 underlying the first portion of the spacer material film 5 begins to be exposed. Since the spacer material film 5 is etched by 9±0.1 nm at the time t1, as shown in FIG. 4B, the second portion of the spacer material film 5 overlying the surface of the semiconductor substrate 2 has a film thickness of 1±0.1 nm.

Next, the etching rate is calculated in accordance with the film thickness of 9±0.1 nm and the time t1 (Step S6 in FIG. 2). However, the etching rate thus calculated has an error of about 1.1% with respect to an ideal etching rate at which the first portion of the spacer material film 5 is etched by its film thickness of 9 nm. The time t3 is estimated in accordance with the etching rate thus calculated (Step S7 in FIG. 2). Also, the second portion of the spacer material film 5 overlying the surface of the semiconductor substrate 2 is further etched up to the time t5 by, for example, 0.8 nm (Step S8 in FIG. 2). Taking the error of 1.1% of the calculated etching rate into consideration, the second portion of the spacer material film 5 overlying the surface of the semiconductor substrate 2 is etched by about 0.8±0.01 nm.

Finally, the second portion of the spacer material film 5 overlying the surface of the semiconductor substrate 2 can be etched by 9.8±0.11 nm. As a result, the etching condition can be changed over to the another suitable one that the C/F ratio is made larger than that of the former etching condition, and the etching selectivity between the spacer material film 5 and the semiconductor substrate 2 is made larger than that of the former etching condition right before the surface of the semiconductor substrate 2 underlying the second portion of the spacer material film 5 is exposed.

Note that, in the case where the film having the uniform film thickness is etched in one step as in the conventional method, when the spacer material film 5 with a film thickness of 10 nm is etched, the spacer material film 5, for example, must be processed with an amount of etched spacer material film 5 as 9±0.9 nm by taking the error of ±10% into consideration. As a result, it is the possibility that the etching condition must be changed over to another suitable one with a lot of spacer material film 5 being left on the semiconductor substrate 2.

In addition, when the timing at which the etching condition is changed over to another suitable one is estimated without calculating the etching rate in accordance with the film thickness of 9±0.1 nm, and the time t1, 0.8 nm in amount of etched spacer material film 5 becomes 0.8±0.08 nm by taking the error of ±10% into consideration. As a result, the etching precision is slightly reduced.

Since the processes in and after the process for etching the spacer material film 5 are the same as those in the first embodiment, the descriptions thereof are omitted here for the sake of simplicity.

According to the second embodiment of the present invention, although the process for measuring the film thickness w1 of the first portion of the spacer material film 5 overlying the surface of the upper portion of the gate electrode 4 in the first embodiment is omitted, the offset spacer 7 having the vertical portion in the vicinity of the boundary between the semiconductor substrate 2 and the offset spacer 7 can be formed more precisely than the conventional one without largely abrading the surface of the semiconductor substrate 2. The process for measuring the film thickness w1 must be carried out for the semiconductor device 1 which is brought out from the chamber once. Therefore, the omission of that process makes it possible to largely shorten the time and to largely save the labor.

A third embodiment of the present invention is different from the first embodiment of the present invention in that a position of the first portion of the spacer material film 5 which is previously thinned is shifted from that of the first portion of the spacer material film 5 in the first embodiment. Note that, the same respects as those of the first embodiment are omitted here for the sake of simplicity.

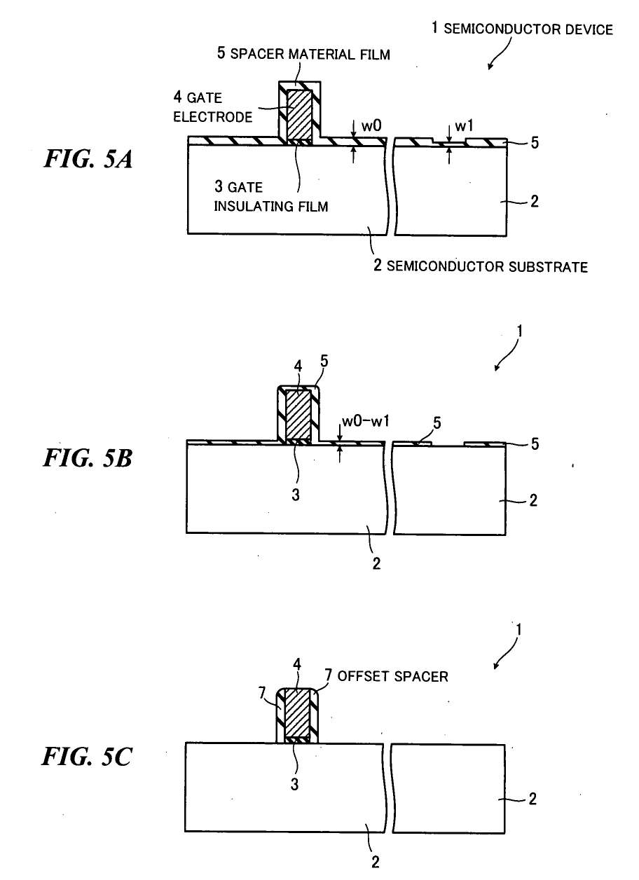

FIGS. 5A to 5C are respectively cross sectional views showing processes for fabricating a semiconductor device according to the third embodiment of the present invention.

Firstly, up to the process for depositing the spacer material film 5 so as to cover the semiconductor substrate 2 and the gate electrode 4 and so as to have the film thickness w0 as shown in FIG. 1B is carried out similarly to that in the first embodiment.

Next, as shown in FIG. 5A, a portion of the spacer material film 5 overlying a portion (such as a dicing line) of the semiconductor substrate 2 which is not used for the semiconductor device is thinned by, for example, utilizing the lithography method and the RIE method (Step S2 in FIG. 2). After that, a film thickness w1 of the thinned portion (first portion) of the spacer material film 5 is measured by using the instrument for measuring a film thickness (Step S3 in FIG. 2).

After that, the spacer material film 5 is started to be etched under a condition that the C/F ratio is small, and the etching selectivity between the spacer material film 5 and the semiconductor substrate 2 is small by using the etching gas such as the fluorocarbon system gas while the emission intensity of the plasma is monitored by using the end point monitor (Step S4 in FIG. 2).

After start of the etching of the spacer material film 5, the time t1 shown in FIG. 3 is detected by using the end point monitor (Step S5 in FIG. 2). In this case, t1 shown in FIG. 3 is the time at which the thinned first portion, with the film thickness w1, of the spacer material film 5 is etched, so that the surface of the portion of the semiconductor substrate 2 which is not used for the semiconductor device begins to be exposed. Here, since the film thickness w1 is previously measured by using the instrument for measuring a film thickness, the etching rate can be calculated in real time in accordance with the calculation of w1/t1 (Step S6 in FIG. 2). FIG. 5B shows a state of the semiconductor device 1 in the middle of fabrication at the time t1. A film thickness of the portion (second portion) of the spacer material film 5 overlying each of the surface of the semiconductor substrate 2 and the surface of the upper portion of the gate electrode 4 is equal to or approximately equal to a value of (w0-w1).

In addition, the time t3 at which the second portion with the film thickness w0 of the spacer material film 5 overlying the surface of the semiconductor substrate 2 is etched, so that the surface of the semiconductor substrate 2 underlying the second portion of the spacer material film 5 begins to be exposed can be estimated in accordance with the calculated etching rate (Step S7 in FIG. 2).

Next, as shown in FIG. 5C, at the time t5 right before the time t3, the etching condition is changed over to another suitable one that the C/F ratio is made larger than that of the former etching condition, and the etching selectivity between the spacer material film 5 and the semiconductor substrate 2 is made larger than that of the former etching condition, and under this etching condition, the etching is performed (Step S8 in FIG. 2). Thus, the second portion of the spacer material film 5 overlying the surface of the semiconductor substrate 2 is removed, so that the offset spacer 7 is formed from the portion of the spacer material film 5 left on the side surfaces of the gate insulating film 3 and the gate electrode 4 (Step S9 in FIG. 2).

Since the later processes are the same as those in the first embodiment, the descriptions thereof are omitted here for the sake of simplicity.

According to the third embodiment of the present invention, although the thinned portion (first portion) of the spacer material film 5 is made different from that of the spacer material film 5 in the first embodiment, it is possible to obtain the same effects as those of the first embodiment. As can be seen from this fact, any suitable portion may be selected as the thinned portion of the spacer material film 5 as long as it allows the emission intensity of the plasma during the etching to be monitored.

It should be noted that the present invention is not intended to be limited to the above-mentioned embodiments, and the various changes thereof can be implemented by those skilled in the art without departing from the gist of the invention. For example, although the emission intensity of the plasma during the etching is monitored in each of the above-mentioned embodiments, the object for the monitoring is not limited to the emission intensity of the plasma, and, for example, an impedance of the plasma may be monitored instead. In this case, a change in impedance of the plasma when the surface of the semiconductor substrate 2 or the like underlying the spacer material film 5 is exposed is detected as the characteristic value of the plasma.

In addition, the material for the spacer material film 5, and the etching gas are not limited to those described in the above-mentioned embodiments. For example, when the spacer material film 5 is made of a silicon nitride, and is etched by using an etching gas containing therein C such as the fluorocarbon system gas, an emission intensity of a plasma which emits a light with a wavelength of 387 nm due to a C—N bond can be monitored during the etching. In addition, when the spacer material film 5 is formed from an organic film, and is etched by using at least any one of an O containing gas such as an O₂ gas, an N containing gas such as an N₂ gas or an NH₃ gas, and an H containing gas such as an H₂ gas, it is possible to monitor an emission intensity of a plasma which emits a light with a wavelength of 484 nm due to a C—O bond, an emission intensity of a plasma which emits a light with a wavelength of 387 nm due to a C—N bond, or an emission intensity of a plasma which emits a light with a wavelength of 431 nm due to a C—H bond.

Moreover, the material for the film to be processed is not limited to those insulating films as described above, and thus the film to be processed can be generally applied to the formation as well of any of other members other than the offset spacer.

In addition, it should be noted that the constituent elements of the above-mentioned embodiments can be arbitrarily combined with one another without departing from the gist of the invention.

What is claimed is:

1. A method of fabricating a semiconductor device, comprising:
forming a film to be processed having a first film thickness on a semiconductor substrate;
forming a region, within the film to be processed, having a second film thickness thinner than the first film thickness by processing a part of the film to be processed;
processing the film to be processed having the region of the second film thickness formed therein by utilizing a dry etching method while a change in characteristic value of a plasma is monitored;
detecting a first timing at which a member right under the region, within the film to be processed, which had the second film thickness before the processing performed by utilizing the dry etching method begins to be exposed in accordance with the change in characteristic value of the plasma during the processing performed by utilizing the dry etching method; and
estimating a second timing right before a member right under a region, of the film to be processed, which had the first film thickness before the processing performed by utilizing the dry etching method begins to be exposed in accordance with the first timing, and changing an etching condition for the dry etching over to another one at the second timing.

2. The method of fabricating a semiconductor device according to claim 1, wherein the second film thickness of the film to be processed ranges from 70% to 90% of the first film thickness.

3. The method of fabricating a semiconductor device according to claim 1, wherein estimating the second timing comprises:
measuring the second film thickness of the film to be processed;
calculating an etching rate in accordance with the second film thickness of the film to be processed, and the first timing; and
obtaining the second timing in accordance with the first film thickness of the film to be processed, the first timing, and the etching rate.

4. The method of fabricating a semiconductor device according to claim 1, wherein the characteristic value of the plasma is either an emission intensity or impedance of the plasma.

5. The method of fabricating a semiconductor device according to claim 1, wherein the etching condition for the dry etching for the film to be processed is changed at the second timing to another one that an etching selectivity between the film to be processed and the semiconductor substrate is made larger than that of the former etching condition.

6. The method of fabricating a semiconductor device according to claim 5, wherein the dry etching for the film to be processed is performed by using a fluorocarbon system gas, and the etching condition for the dry etching for the film to be processed is changed at the second timing to another one that a C/F ratio of the fluorocarbon system gas is made larger than that of the fluorocarbon system gas of the former etching condition.

7. The method of fabricating a semiconductor device according to claim 1, wherein the film to be processed is a silicon oxide film, and the dry etching is performed by using a gas containing therein F.

8. The method of fabricating a semiconductor device according to claim 7, wherein the gas containing therein F is a fluorocarbon system gas.

9. The method of fabricating a semiconductor device according to claim 1, wherein the film to be processed is a silicon nitride film, and the dry etching is performed by using a fluorocarbon system gas.

10. The method of fabricating a semiconductor device according to claim 1, wherein the film to be processed is an organic film, and the dry etching is performed by using at least one of a gas containing therein O, a gas containing therein N, and a gas containing therein H.

11. A method of fabricating a semiconductor device, comprising:
forming a gate electrode on a semiconductor substrate through a gate insulating film;
forming a film to be processed having a first film thickness on the semiconductor substrate, and an upper surface and a side surface of the gate electrode;
applying an organic film onto the film to be processed;
etching back the organic film by utilizing a dry etching method until a portion of the film to be processed overlying the upper surface of the gate electrode is exposed;
thinning the exposed portion of the film to be processed overlying the upper surface of the gate electrode by utilizing a dry etching method until the exposed portion of the film to be processed has a second film thickness;
removing the organic film by utilizing an ashing technique after thinning the exposed portion of the film to be processed overlying the upper surface of the gate electrode by utilizing the dry etching method;
processing the film to be processed by utilizing a dry etching method while a change in characteristic value of a plasma is monitored after removing the organic film by utilizing the ashing technique;
detecting a first timing at which the gate electrode begins to be exposed in accordance with the change in characteristic value of the plasma;
estimating a second timing right before the semiconductor substrate begins to be exposed in accordance with the first timing, and changing an etching condition for the dry etching over to another one at the second timing; and
removing the film to be processed overlying the semiconductor substrate, thereby leaving the film to be processed on the side surface of the gate electrode.

12. The method of fabricating a semiconductor device according to claim 11, wherein the second film thickness of the film to be processed ranges from 70% to 90% of the first film thickness.

13. The method of fabricating a semiconductor device according to claim 11, wherein estimating the second timing comprises:
measuring the second film thickness of the film to be processed;
calculating an etching rate in accordance with the second film thickness of the film to be processed, and the first timing; and
obtaining the second timing in accordance with the first film thickness of the film to be processed, the first timing, and the etching rate.

14. The method of fabricating a semiconductor device according to claim 11, wherein the characteristic value of the plasma is either an emission intensity or impedance of the plasma.

15. The method of fabricating a semiconductor device according to claim 11, wherein the etching condition for the dry etching for the film to be processed is changed at the second timing to another one that an etching selectivity between the film to be processed and the semiconductor substrate is made larger than that of the former etching condition.

16. The method of fabricating a semiconductor device according to claim 15, wherein the dry etching for the film to be processed is performed by using a fluorocarbon system gas, and the etching condition for the dry etching for the film to be processed is changed at the second timing to another one that a C/F ratio of the fluorocarbon system gas is made larger than that of the fluorocarbon system gas of the former etching condition.

17. The method of fabricating a semiconductor device according to claim 11, wherein the film to be processed is a silicon oxide film, and the dry etching for the film to be processed is performed by using a fluorocarbon system gas.

18. The method of fabricating a semiconductor device according to claim 11, wherein the film to be processed is a silicon nitride film, and the dry etching for the film to be processed is performed by using a fluorocarbon system gas.

19. The method of fabricating a semiconductor device according to claim 11, wherein each of the dry etching and the ashing for the organic film is performed by using an O₂ gas, and the dry etching for the film to be processed is performed by using a fluorocarbon system gas.

20. The method of fabricating a semiconductor device according to claim 11, wherein etching back the organic film, thinning the exposed portion of the film to be processed overlying the upper surface of the gate electrode by utilizing the dry etching method, removing the organic film by utilizing the ashing technique, processing the film to be processed by utilizing the dry etching method, and removing the film to be processed overlying the semiconductor substrate, thereby leaving the film to be processed on the side surface of the gate electrode are carried out in the same chamber.
